(19) United States
(12) Patent Application Publication
(10) Pub. No.: US 2013/0141126 A1
(43) Pub. Date: Jun. 6, 2013

(54) SIMULATION TEST CARD

(71) Applicants: LEI LIU, Shenzhen City (CN); XIAO-FENG MA, Shenzhen City (CN)

(72) Inventors: LEI LIU, Shenzhen City (CN); XIAO-FENG MA, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/340,633

(22) Filed: Dec. 29, 2011

(30) Foreign Application Priority Data
Dec. 1, 2011 (CN) 201110392898.8

(51) Int. Cl. G01R 31/00

(52) U.S. Cl. 324/750.03

(57) ABSTRACT

A simulation test card to simulate a peripheral card to be inserted into a system to be tested includes a board, an edge connector formed on a bottom side of the board, and a first heating circuit. The first heating circuit includes a number of first switches, a number of first resistors, and a heating element. First terminal of the first switches are connected to a power pin of the edge connector. A first terminal of each first switch is connected to a first terminal of the first heating element through a corresponding first resistor. A second terminal of the first heating element is connected to a ground pin of the edge connector. Each of the switches can be selectively switched to make the first heating circuit generate different heat.

### BACKGROUND

1. Technical Field

The present disclosure relates to a simulation test card.

2. Description of Related Art

For endurance testing of servers, the servers may be placed in a heat chamber and the servers subjected to extremes of high and low temperatures. However, some peripheral cards, such as peripheral component interconnection express (PCIe) cards, mounted in the servers may be damaged in such environment.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present disclosure. Moreover, in the drawings, all the views are schematic, and like reference numerals designate corresponding parts throughout the several views.

FIG. 1 is an isometric view of an exemplary embodiment of a simulation test card, wherein the simulation test card includes a first heating circuit and a second heating circuit.

FIG. 2 is a circuit diagram of the first heating circuit of FIG. 1.

FIG. 3 is a circuit diagram of the second heating circuit of FIG. 1.

FIG. 4 is an isometric view of the simulation test card of FIG. 1 inserted into a socket of a test system.

### DETAILED DESCRIPTION

The disclosure, including the accompanying drawing in which like references indicate similar elements, is illustrated by way of example and not by way of limitation. It should be noted that references to “an” or “one” embodiment in this disclosure are not necessarily to the same embodiment, and such references mean at least one.

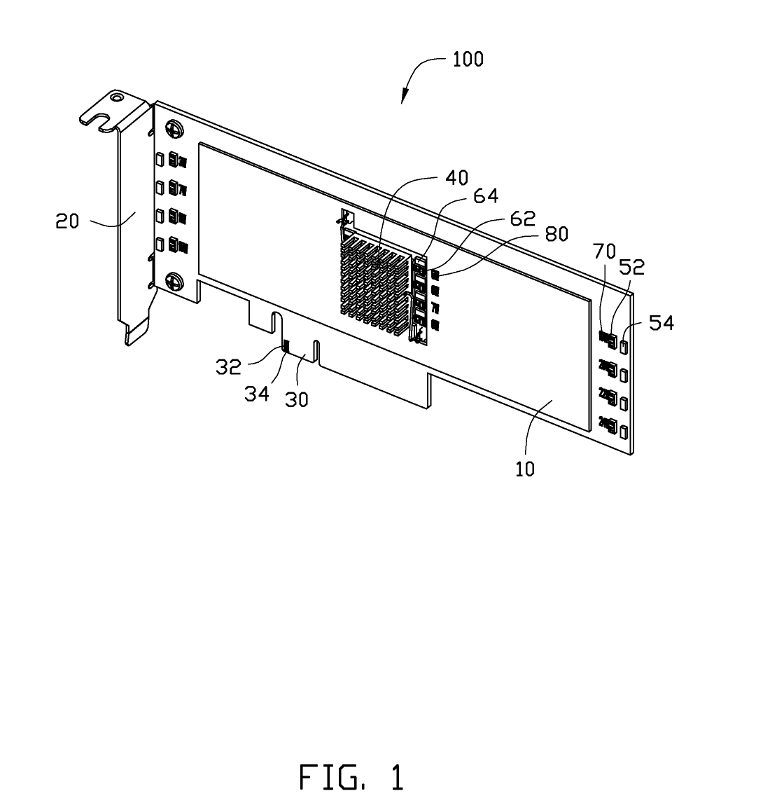

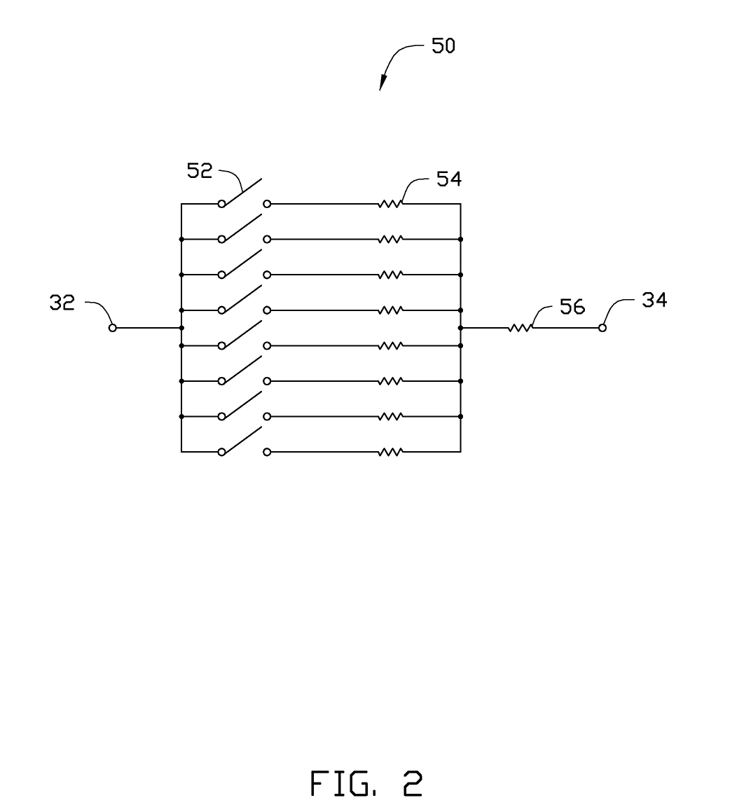

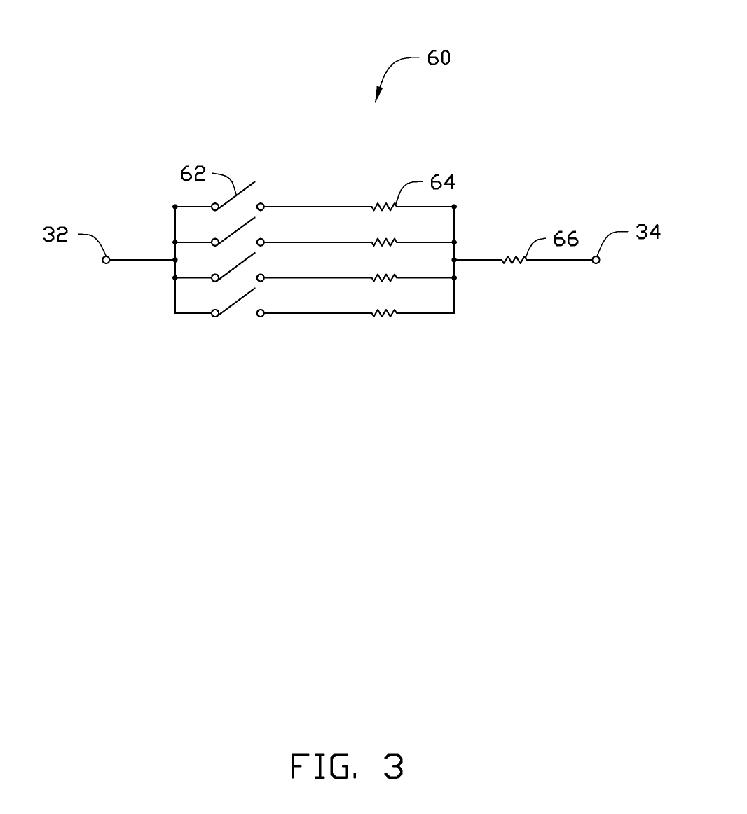

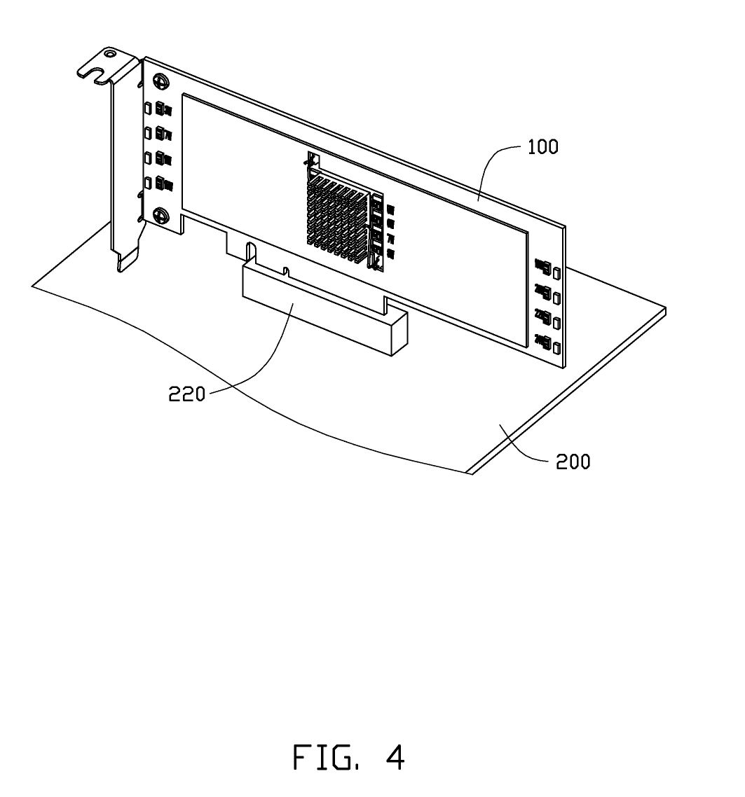

Referring to the FIGS. 1 to 4, an embodiment of a simulation test card 100 is used to simulate a peripheral card, such as a peripheral component interconnection (PCI) express card, to be inserted into a socket 220 of a system 200 to be tested. The simulation test card 100 includes a board 10, a supporting bracket 20 fixed to an end of the board 10, an edge connector 30 formed on a bottom side of the board 10, a heat sink 40 mounted on the board 10, a first heating circuit 50 arranged on the board 10, and a second heating circuit 60 arranged on the board 10. The heat sink 40 is mounted above the second heating circuit 60 to dissipate heat generated by the second heating circuit 60.

The edge connector 30 includes a power pin 32 and a ground pin 34. When the edge connector 30 is inserted to the socket 220, the power pin 32 receives a voltage from the system 200 through the socket 220. The ground pin 34 is connected to a ground terminal of the system 200 through the socket 220.

The first heating circuit 50 is arranged on two ends of the board 10 to simulate a main body of the PCIe card to generate heat. The first heating circuit 50 includes a plurality of first switch 52, a plurality of first resistors 54, and a first heating element, such as a first heating resistor 56. One first switch 52 is connected to one first resistor 54 in series. First terminals of the first switches 52 are connected to the power pin 32. A second terminal of each first switch 52 is connected to a first terminal of the first heating resistor 56 through a corresponding first resistor 54. A second terminal of the first heating resistor 56 is connected to the ground pin 34. A plurality of power values are labeled on the board 10, and located at one side of the corresponding first switches 52. Each power value stands for the heating power of the first heating resistor 56 when the corresponding first switch 52 is turned on. In the embodiment, the resistance of each of the first resistors 54 is different. Only one first switch 52 is turned on every time. The first switches 52 can be selectively switched to make the first heating resistor 56 simulate different PCIe cards to generate heat.

The second heating circuit 60 is mounted on a middle of the board 10 to simulate an integrated chip on the PCIe card to generate heat. The heating circuit 60 includes a plurality of second switches 62, a plurality of second resistors 64, and a second heating element, such as a second heating resistor 66. One second switch 62 is connected to one second resistor 64 in series. First terminals of the second switches 62 are connected to the power pin 32. A second terminal of each second switch 62 is connected to a first terminal of the second heating resistor 66 through a corresponding second resistor 64. A second terminal of the second heating resistor 66 is connected to the ground pin 34. A plurality of power values are labeled on the board 10, and located at one side of the corresponding second switches 62. Each power value stands for the heating power of the second heating resistor 66 when the corresponding second switch 62 is turned on. In the embodiment, the resistance of each of the second resistors 64 is different. Only one second switch 62 is turned on every time. The second switches 62 can be selectively switched to make the second heating circuit 60 simulate different integrated chips to generate heat.

Although numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the embodiments to the full extent indicated by the broad general meaning of the terms in which the appended claims are expressed.

What is claimed is:

1. A simulation test card to simulate a peripheral card to be inserted into a system to be tested, the simulation test card comprising:
a board;
an edge connector formed on a bottom side of the board to be inserted into a socket of the system to be tested, the edge connector comprising a power pin and a ground pin; and
a first heating circuit arranged on the first board, the first heating circuit comprising:
at least two first switches, each first switch comprising a first terminal connected to the power pin of the edge connector and a second terminal;
at least two first resistors each comprising a first terminal connected to the second terminal of a corresponding first switch, and a second terminal; and
a first heating element comprising a first terminal connected to the second terminals of the at least two first switches, and a second terminal connected to the ground pin of the edge connector;
wherein each of the at least two first switches is selectively switched to make the first heating circuit generate different heat.

2. The simulation test card of claim 1, further comprising a second heating circuit arranged on the board, wherein the second heating circuit comprising at least two second switches, at least two second resistors, and a second heating element, first terminals of the second switches are connected to the power pin of the edge connector, a second terminal of each second switch is connected to a first terminal of the second heating element through a corresponding second resistor, a second terminal of the second heating element is connected to the ground pin of the edge connector, each of the at least two second switches are selectively switched to make the second heating circuit to generate different heat.

3. The simulation test card of claim 2, further comprising a heat sink mounted on the board, and located above the second heating circuit to dissipate heat generated by the second heating circuit.

4. The simulation test card of claim 2, wherein the first and second heating elements are two heating resistors.

5. The simulation test card of claim 2, wherein the first heating circuit is arranged on two ends of the board, the second heating circuit is arranged on a middle of the board.

6. The simulation test card of claim 2, wherein a power value is labeled on the board, and located on one side of each first switch.
